(19) United States
(12) Patent Application Publication
(10) Pub. No.: US 2009/0152675 A1
(43) Pub. Date: Jun. 18, 2009

(54) INDUCTOR OF SEMICONDUCTOR DEVICE AND METHOD FOR MANUFACTURING THE SAME

(76) Inventor: Su-Tae Kim, Jinan-gun (KR)

Correspondence Address: SHERR & VAUGHN, PLLC, 620 HERNDON PARKWAY, SUITE 200, HERNDON, VA, 20170, US

(21) Appl. No.: 12/330,608

(22) Filed: Dec. 9, 2008

(30) Foreign Application Priority Data
Dec. 17, 2007 (KR) 10-2007-0132393

(51) Int. Cl. H01L 27/06; H01L 21/62

(52) U.S. Cl. 257/531; 438/3; 257/E21.52; 257/E27.013

(57) ABSTRACT

In a semiconductor device having a first region formed with the inductor and a second region formed with transistors, the inductor includes a deep well region formed in the silicon substrate beneath the first and second regions, a well region formed on the deep well region in the second region, N type shield regions formed to have the same depth as the well region, and P type shield regions arranged to alternate with the N type shield regions, the transistors formed on the silicon substrate in the second region, an insulating film formed over an entire surface of the silicon substrate such that the insulating film covers the transistors, and a metal line formed on the insulating film in the first region such that the metal line corresponds to the N and P type shield regions.

The present application claims priority under 35 U.S.C. 119 to Korean Patent Application No. 10-2007-0132393 (filed on Dec. 17, 2007), which is hereby incorporated by reference in its entirety.

### BACKGROUND

Because of recent advances in the wireless mobile communication field, the need for radio-frequency resources has increased. For other reasons as well, the demand for devices and circuits operating at radio frequencies has increased. Such devices and circuits are classified as radio-frequency (RF) elements and integrated circuits (ICs) because they operate in relatively high frequency ranges. Also, complementary metal-oxide semiconductors (CMOSs) may have excellent RF characteristics depending on various of micro-machining techniques. Since such a CMOS is based on silicon, the manufacture of an inexpensive chip, using well-developed process techniques may be possible. In the case of a system-on-chip (SOC), it may also possible to integrate both the intermediate-frequency-band parts and the digital system parts. Accordingly, CMOS manufacturing techniques may be suitable for the manufacture of a single integrated RF chip.

Related RF IC techniques encompass device manufacturing techniques, circuit design techniques, and RF packaging techniques. Accordingly, developing a competitive RF-CMOS device may involve balancing improvements of the above-mentioned techniques and, also, reducing manufacturing costs. To this end, it is desirable to simplify and stabilize the variety of processes involved in manufacturing such a device.

An RF-CMOS or bipolar/BiCMOS device may include an RF MOSFET, an inductor, a varactor, an MIM capacitor, and a resistor. Of particular interest is the conductor which occupies the largest chip area. Furthermore, the RF characteristics of the inductor may be considerably limited due to parasitic capacitance and resistance components caused by materials around the inductor, the structure of the inductor, and the material of the inductor.

### SUMMARY

Accordingly, embodiments relate to an inductor of a semiconductor device and a method for manufacturing the same, which may enhance the quality factor of the inductor. An inductor of a semiconductor device having a first region formed with the inductor and a second region formed with transistors, includes a deep well region formed in the silicon substrate beneath the first and second regions; a well region formed on the deep well region in the second region; N type shield regions formed to have the same depth as the well region, and P type shield regions arranged to alternate with the N type shield regions. Also included are the transistors formed on the silicon substrate in the second region; an insulating film formed over an entire surface of the silicon substrate such that the insulating film covers the transistors; and a metal line formed on the insulating film in the first region such that the metal line corresponds to the N and P type shield regions.

Embodiments relate to a method for manufacturing an inductor of a semiconductor device having a first region formed with the inductor and a second region formed with transistors. In accordance with this method, manufacturing the inductor includes selectively implanting first-type impurity ions into a silicon substrate, thereby forming first-type shield regions in the first region and forming first-type well regions in the second region; selectively implanting second-type impurity ions into the silicon substrate, thereby forming second-type shield regions in the first region and forming second-type well regions in the second region; forming the transistors in the first and second-type well regions, respectively; forming an insulating film on the silicon substrate; and forming a metal line on the insulating film above the first and second-type shield regions.

Embodiments relate to an inductor having a high Q factor that can be implemented in a chip and may be manufactured without separate, additional masks and processes. Furthermore, a reduction in self resonating frequency (SRF) caused by a parasitic capacitance may be suppressed. Also, because the shield regions may be formed simultaneously with the wells of the semiconductor device, the overall process is made simpler and more economical. Reliability may also be improved because shielding the displacement current generated by the inductor is possible.

### DRAWINGS

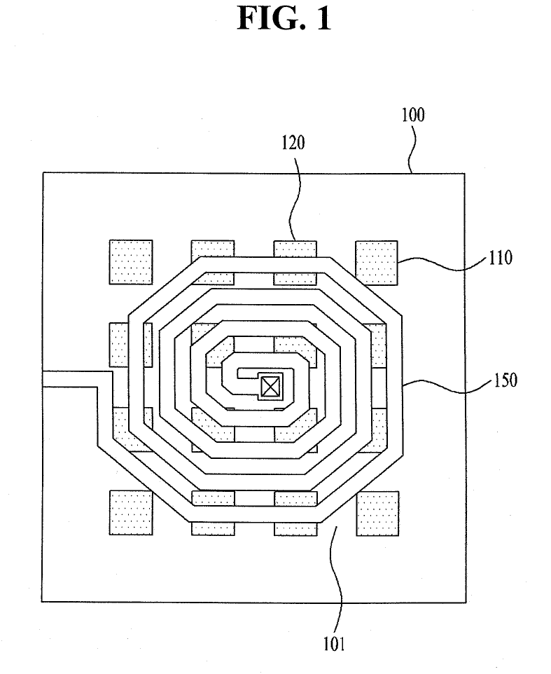

Example FIG. 1 is a plan view illustrating an inductor according to embodiments.

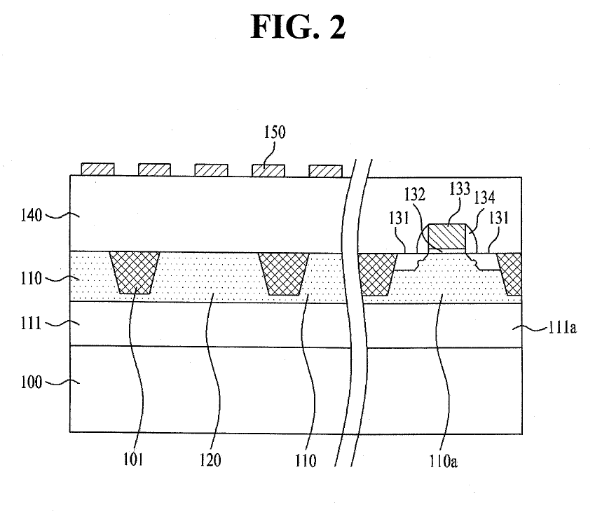

Example FIG. 2 is a sectional view illustrating a semiconductor device according to embodiments.

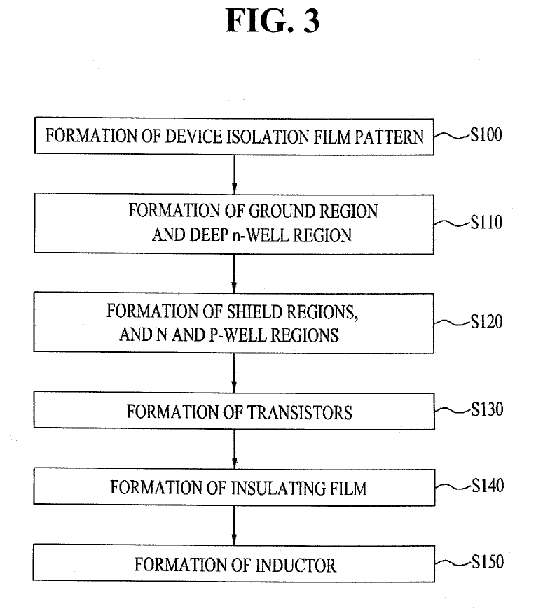

Example FIG. 3 is a flow chart illustrating a method for manufacturing an inductor according to embodiments.

### DESCRIPTION

In the description below, it will be understood that when a layer (or film), a region, a pad, a pattern or a structure are referred to as being ‘on/above/over/upper’ another layer, region, pad, pattern or substrate, it can be directly in contact with another layer, region, pad, pattern or substrate, or one or more intervening layers, regions, pads, patterns or structures may also be present. Example FIG. 1 is a plan view illustrating an inductor according to embodiments and example FIG. 2 is a sectional view illustrating a semiconductor device according to embodiments.

The inductor according to the example figures may be implemented in a semiconductor device. For example, the semiconductor device may be a CMOS device, an NMOS device, or a PMOS device. The inductor includes a metal line 150, and shield regions 110 and 120. In operation, a magnetic field would be generated in the inductor due to the resistance of the metal line 150 and the current flowing through the metal line 150. This magnetic field functions as a factor causing a degradation in the Q factor of the inductor. However, as shown, this factor can be removed, or reduced, by the shield regions 110 and 120.

The shield regions 110 and 120 may be formed by implanting impurity ions into a silicon substrate 100. The shield regions 110 and 120 may be connected to a ground, so that a displacement current generated in the inductor can be outwardly discharged through the shield regions 110 and 120. The shield regions 110 and 120, and metal line 150 of the inductor may be formed in the process of forming a semiconductor device on the silicon substrate 100. Accordingly, the inductor, which has a small size, can be manufactured through a simple process, without using a separate process and a separate mask process. Also, according to embodiments, a single passive device such as the inductor can be implemented in one chip, together with other semiconductor devices.

As shown in example FIGS. 1 and 2, a device isolation film pattern 101 may be formed on, or over, the silicon substrate 100. The device isolation film pattern 101 may be formed by forming trenches in the silicon substrate 100, and then filling the trenches with, for example, an oxide film. For example, the device isolation film pattern 101 may be a shallow trench isolation pattern. A ground region 111 and a deep N-well region 111a may be formed in the silicon substrate 100 beneath the device isolation film pattern 101. The ground region 111 may correspond to substantially the entire portion of the inductor. The deep N-well region 111a may be formed in a logic circuit region of the semiconductor device, to which the inductor is applied. Thus, the ground region 111 and deep N-well region 111a may be formed in the same process.

Active regions may be defined in the silicon substrate 100 by the device isolation pattern 101. For the formation of the shield regions 110 and 120, impurity ions may be implanted into the active regions. For example, according to embodiments, the shield regions 110 and 120 may be formed in regularly-spaced and repetitive patterns. The shield regions 110 and 120 may include P type shield regions 110 and N type shield regions 120 formed in the active regions defined by the device isolation film pattern 101.

Each P type shield region 110 is a region in which P type impurity ions are implanted, whereas each N type shield region 120 is a region in which N type impurity ions are implanted. Each P type shield region 110 may, for example, be formed in the same process as forming a P-well region of an NMOS transistor in a logic circuit of the semiconductor device and each N type shield region 120 may be formed in the same process as forming an N-well region of a PMOS transistor in the logic circuit of the semiconductor device.

The P and N type shield regions 110 and 120 may be alternately formed to form a PNP structure capable of generating a diffusion capacitance. In this case, PN and NP diffusion capacitances provide an effect similar to serial capacitors that are formed in an equivalent circuit of the inductor between a silicon substrate and an oxide film formed on the silicon substrate. Accordingly, total capacitance may be minimized so that a Q-factor improvement effect can be obtained.

The N type shield regions 120 and P type shield regions 110 may be formed over the deep N-well region 111a. In particular, the N type shield regions 120 may be connected to ground, or in other words, allow the displacement current to flow to the ground region 111.

Since the shield regions 110 and 120 may be formed in accordance with the method for forming NMOS and PMOS well regions in the logic region of the semiconductor device, the formation of the shield regions 110 and 120 may be achieved through an ion implantation process executed, for example, two times. Accordingly, where the shield regions 110 and 120 are formed in the form of upper and lower well regions, each N type shield region 120 and each P type shield region 110 may be the upper and lower well regions, respectively. Alternatively, the impurity ion types of the shield regions 110 and 120 may be reversed from those shown in the example figures.

Although the adjacent P type and N type shield regions 110 and 120 may be arranged in contact with each other, no current flows between the shield regions 110 and 120 due to a capacitor effect obtained by the implantation of impurity ions of different types in respective shield regions 110 and 120. However, a current path may be formed between the N type shield region 120 and the deep N-well region 111a, in which impurity ions of the same type are implanted. Accordingly, it is possible to remove the displacement current generated in the inductor by connecting the displacement current to the ground.

Because the shield regions 110 and 120 may be formed in the process of forming wells in the logic circuit without using a separate ion implantation mask process, it is possible to simplify the formation process for the shield regions 110 and 120, and to reduce manufacturing costs. After the formation of the shield and well regions, NMOS and PMOS transistors may be formed in the active regions of the silicon substrate corresponding to the logic circuit region.

Referring to example FIG. 2, gate patterns may be formed in the active regions of the silicon substrate 100 formed with the deep N-well region 111a and P-well regions 110a. Each gate pattern may include a gate insulating film 132 and a gate electrode 133. Side walls 134 may be formed at respective side surfaces of each gate pattern. Source and drain regions 131, in which N type impurity ions may be implanted in a high concentration, are formed in the silicon substrate 100 at opposite sides of each gate pattern, respectively. Thus, an NMOS transistor may be formed. Alternatively, a PMOS transistor may instead be formed on the silicon substrate 100 using similar steps but reversing the ion types of the impurities used.

At least one insulating film 140 is formed on, or over, the silicon substrate 100 formed with the shield regions 110 and 120, and the transistors. On, or over, the insulating film 140, the inductor including the metal line 150 may be formed. The metal line 150 may, for example, be formed to have a planar spiral geometry structure having a plurality of bending portions. In accordance with embodiments, the inductor 100 may have a high Q factor and can be implemented in a chip, thereby maximizing its utility.

Example FIG. 3 is a flow chart illustrating a method for manufacturing the inductor according to embodiments. Because such an inductor can be formed together with a semiconductor device such as a transistor or capacitor, in the manufacture of the semiconductor device, the inductor can be mounted in one chip.

In accordance with the flow chart of example FIG. 3, the device isolation film pattern 101 may be first formed on, or over, the silicon substrate 100 (S100). The device isolation film pattern 101 helps define the shield regions 110 and 120 for shielding electric and magnetic fields undesirably generated in the inductor. The device isolation film pattern 101 may also help define the active regions where transistors will be formed, in the logic circuit region.

Thereafter, impurity ions may be deeply implanted into the silicon substrate 100, as compared to the device isolation film pattern 101, to form the deep N-well region 111a in the logic circuit region. The ground region 111 may also be formed in the inductor formation region (S100). Impurity ions may be implanted into the silicon substrate 100, to form N and P-well regions in the active regions of the logic circuit region. At this time, the shield regions 110 and 120 may also be formed in the inductor formation region (S120).

The N type shield regions 120 may be formed during the formation of the N-well regions and the P type shield regions 110 may be formed during the formation of the P-well regions such that the P type shield regions 110 and N type shield regions 120 may be alternately arranged. The formation of the N-well regions and N type shield regions 120 may be achieved by executing an ion implantation process for N type impurity ions under the condition in which the P-well regions and P type shield regions 110 are covered by a photoresist pattern. Similarly, the formation of the P-well regions and P type shield regions 110 may be achieved by executing an ion implantation process for P type impurity ions under the condition in which the N-well regions and N type shield regions 120 are covered by a photoresist pattern.

Thereafter, transistors including source and drain ion implantation regions may be formed in the silicon substrate 100 formed with the N and P-well regions (S130). At least one insulating film 140 and metal lines connected to the transistors may then be formed on the silicon substrate 100 region with the transistors (S140). The inductor, which includes the metal line 150, may be formed on the insulating film 140 in regions corresponding to the shield regions 110 and 120 (S150). The shield regions 110 and 120 may function to connect a displacement current generated in the inductor to the ground, thereby enhancing the Q factor of the inductor.

Because the shield regions 110 and 120 can be formed simultaneously with the wells of the semiconductor device in the process of forming the wells, the formation process is relatively simple and economical. Accordingly, a high productivity may be obtained. Also, because the displacement current generated by the inductor can be shielded, the manufactured device may have excellent radio-frequency characteristics, thereby enhancing its reliability.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A semiconductor device having a first region formed with an inductor and a second region formed with at least one transistor, comprising:
a deep well region formed in the silicon substrate beneath the first and second regions;
a well region formed over the deep well region in the second region;
one or more N-type shield regions formed to have substantially a same depth as the well region, and one or more P-type shield regions arranged to alternate with the N-type shield regions;
the at least one transistor formed over the silicon substrate in the second region;
an insulating film formed over the silicon substrate; and
a metal line formed over the insulating film in the first region such that the metal line is formed over the N-type and P-type shield regions.

2. The semiconductor device according to claim 1, wherein the insulating film covers the at least one transistor.

3. The semiconductor device according to claim 1, wherein the insulating film is formed over substantially an entire surface of the silicon substrate.

4. The semiconductor device according to claim 1, wherein the well region comprises an N-type well region and a P-type well region.

5. The semiconductor device according to claim 1, further comprising:
a device isolation film pattern formed on the silicon substrate, defining the N-type shield regions and the P-type shield regions.

6. The semiconductor device according to claim 1, wherein the metal line includes a planar spiral geometry structure.

7. The semiconductor device according to claim 1, wherein the deep well region is connected to a ground in the second region.

8. The semiconductor device according to claim 1, wherein one of the P-type and N-type shield regions is connected to a ground in the first region.

9. A method for manufacturing an inductor of a semiconductor device having a first region formed with the inductor and a second region formed with at least one transistor, comprising:
selectively implanting first-type impurity ions into a silicon substrate, thereby forming first-type shield regions in the first region and forming first-type well regions in the second region;
selectively implanting second-type impurity ions into the silicon substrate, thereby forming second-type shield regions in the first region and forming second-type well regions in the second region;
forming the at least one transistor in the first and second-type well regions, respectively;
forming an insulating film over the silicon substrate; and
forming a metal line over the insulating film above the first and second-type shield regions.

10. The method according to claim 9, wherein forming the at least one transistor includes performing ion implantation to form source and drain regions in each of the first and second-type well regions.

11. The method according to claim 9, comprising:
performing an ion implantation process to form a deep well region beneath the first and second-type well regions.

12. The method according to claim 11, wherein a ground region is formed beneath the first and second-type shield regions.

13. The method according to claim 12, wherein the ground region is formed concurrently with forming the deep well region by performing the ion implantation process.

14. The method according to claim 9, wherein the first-type impurity ions are N-type impurity ions, and the second-type impurity ions are P-type impurity ions.

15. The method according to claim 9, comprising:
forming a device isolation film pattern for defining shield regions in the first region of the silicon substrate, and defining active regions in the second region of the silicon substrate.

16. The method according to claim 15, wherein the device isolation film pattern defines the first and second-type shield regions.

17. The method according to claim 15, comprising:
forming a ground region in the first region of the silicon substrate, and forming a deep well region in the second region of the silicon substrate, after the formation of the device isolation film pattern.

18. The method according to claim 17, wherein forming the deep well region comprises:
implanting impurity ions such that the deep well region has an ion implantation depth deeper than an ion implantation depth of the device isolation film pattern.

19. The method according to claim 9, wherein the metal line includes a planar spiral geometry structure.

20. The method according to claim 9, wherein the insulating film is formed over substantially an entire surface of the silicon substrate.
